(19) United States
(12) Patent Application Publication
(10) Pub. No.: US 2006/0189085 A1
(43) Pub. Date: Aug. 24, 2006

(54) Method of forming dual polysilicon gate of semiconductor device

(75) Inventors: Wook-je Kim, Seoul (KR); Yong-chul Oh, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/356,998

(22) Filed: Feb. 17, 2006

(30) Foreign Application Priority Data
Feb. 19, 2005 (KR) 10-2005-0013905

(51) Int. Cl. H01L 21/336

(52) U.S. Cl. 438/283

(57) ABSTRACT

In a method of forming a dual polysilicon gate of a semiconductor device, a polysilicon layer is formed on a substrate divided into an NMOS region and a PMOS region. Then, a p-type impurity is implanted in the PMOS region. A thermal annealing process is performed that causes generation of a compound material at a top surface of the polysilicon layer in the PMOS region as a result of bonding between the p-type impurity and the polysilicon layer. A cleaning process is then performed. During the cleaning process, the compound material decreases an etch rate in the PMOS region, so that a height of the polysilicon layer in the NMOS region is reduced relative to that of the polysilicon layer in the PMOS region. Accordingly, an intended range of a threshold voltage can be obtained by blocking the p-type impurity in the PMOS region from penetrating into a gate insulation layer. Also, by maintaining an increased height of a gate transmission material in the cell region, a resistance increase is thereby prevented.

### CROSS-REFERENCE TO RELATED PATENT APPLICATION

This application claims the benefit of Korean Patent Application No. 10-2005-0013905, filed on Feb. 19, 2005, in the Korean Intellectual Property Office, the disclosure of which is incorporated herein in its entirety by reference.

### BACKGROUND OF THE INVENTION

1. Field of the Invention

The present invention relates to a method of fabricating a semiconductor device, and more particularly, to a method of forming a dual polysilicon gate of a dynamic random access memory (DRAM).

2. Description of the Related Art

As personal electronic devices such as mobile phones have become ubiquitous, research continues to be focused on developing semiconductor devices that can operate at low voltage and high speed.

In a process of forming a gate of a semiconductor memory device such as a dynamic random access memory (DRAM), methods of fabrication that employ silicide or tungsten as a gate material are used obtain a high-speed mode of operation. In addition, to achieve a favorable low voltage operation mode, a dual polysilicon gate fabrication process has been widely employed.

Generally, in the dual polysilicon gate fabrication process, a p-type impurity such as boron (B) or boron difluoride (BF₂) is implanted into a polysilicon layer disposed in a p-channel metal-oxide semiconductor (PMOS) region to form a gate electrode with two different types of impurities. If the polysilicon layer is thin, the implanted p-type impurity penetrates toward a region where a gate insulation layer is formed. As a result, an impurity concentration of a transistor channel is changed, thereby causing a change in the threshold voltage of the resulting transistor. Relative to the impurity concentration of a gate, the threshold voltage changes abruptly, even with a slight change in the impurity concentration of a channel region. The phenomenon of penetration of the p-type impurity toward the gate insulation layer results in widely varying transistor threshold voltages among transistors of a semiconductor device. This wide variation, in turn, results in increased defect generation in the semiconductor device.

FIGS. 1 and 2 are cross-sectional views of a typical dual polysilicon gate for illustrating a conventional method of forming the same.

Referring to FIG. 1, a gate insulation layer 12 is formed on a substrate 10 and a polysilicon layer 14 including an n-type impurity is formed on the gate insulation layer 12. An amorphous silicon layer can also be used instead of the polysilicon layer 14. A mask pattern 16 masking an n-channel metal-oxide semiconductor (NMOS) region of the substrate 10 is formed, and afterwards, a p-type impurity 18 such as B or BF₂ is ion-implanted onto a portion of the polysilicon layer 14 in the PMOS region.

Referring to FIG. 2, the mask pattern 16 is then removed by performing an ashing process and a strip process. A rapid thermal annealing (RTA) process is subsequently applied to activate the ion-implanted p-type impurity 18. Reference numeral 14A represents a polysilicon layer that is ion-implanted with the p-type impurity 18. Then, on top of the polysilicon layer 14 and the ion-implanted polysilicon layer 14A, both of which are thermally annealed, a metal layer 20 is formed to be overlaid with a gate etch mask layer 22. Herein, the metal layer 20 is formed using tungsten or tungsten silicide. A typical-gate process is then performed on the polysilicon layer 14, the ion-implanted polysilicon layer 14A, the metal layer 20 and the gate etch mask layer 22, thereby forming a gate electrode.

If the ion-implanted polysilicon layer 14A is thin, the p-type impurity 18, for instance, boron, that is ion-implanted into the PMOS region, penetrates 24 towards the gate insulation layer 12. However, as described above, this penetration 24 causes variation of the threshold voltage of the transistor, resulting in increased device defect generation.

Currently, the integration scale of semiconductor devices, such as DRAM devices, has largely increased. Thus, as the integration scale advances, the gate area is reduced. A decreased gate area means that the height of the gate should also be continuously decreased. Meanwhile, as the width of the gate in a cell region becomes narrower, the resistance thereof increases sharply, and the height of the gate material, for instance, a gate formed of tungsten silicide, is reduced. It is desired to prevent the resistance of the gate from increasing further.

If the polysilicon layer 14 and the ion-implanted polysilicon layer 14A become thinner in order to lower the height of the gate, the p-type impurity 18 is more likely to penetrate toward the gate insulation layer 12 during the aforementioned dual polysilicon gate formation process. To solve this problem, a method of decreasing the implantation energy when the p-type impurity 18 is ion-implanted in the PMOS region has been suggested. However, this method is limited in that the manufacturing productivity of the semiconductor devices is reduced as the processing time of the ion-implantation process is increased due to the reduced implantation energy.

### SUMMARY OF THE INVENTION

The present invention provides a method of forming a dual polysilicon gate of a semiconductor device, wherein a selectively decreased thickness of a polysilicon layer in an NMOS region and a cell region is achieved by forming a polysilicon layer, performing an ion-implantation process, and performing a cleaning process during a dual polysilicon gate formation process.

In one aspect, the present invention is directed to a method of forming a dual polysilicon gate of a semiconductor device, comprising: forming a polysilicon layer for use in a gate electrode on a substrate divided into a PMOS region and an NMOS region; forming a mask pattern for masking the NMOS region of the substrate; ion-implanting a p-type impurity onto a portion of the substrate exposed by the mask pattern in the PMOS region; removing the mask pattern; performing a rapid thermal annealing process on the substrate to generate a compound material at a top surface of the polysilicon layer in the PMOS region as a result of bonding between the p-type impurity and the polysilicon layer; and cleaning the substrate including the compound material in the PMOS region to reduce a height of the polysilicon layer in the NMOS region relative to a height of the polysilicon layer in the PMOS region.

In one embodiment, the polysilicon layer can be doped with an n-type impurity such as phosphorus (P) and has a thickness preferably ranging from 500 Å to 900 Å.

In another embodiment, the mask pattern can be a photoresist pattern and the p-type impurity may be boron difluoride (BF₂). The ion-implantation of the p-type impurity can be performed at an ion-implantation energy level ranging from 1 KeV to 20 KeV. The mask pattern can be removed through an ashing process and a strip process.

In another embodiment, the rapid thermal annealing process can be carried out at 800° C. to 1,200° C. in an atmosphere of nitrogen gas for 20 seconds to 60 seconds. Also, a trace amount of oxygen gas, for example, 1% to 5% of oxygen gas, can be added to the nitrogen gas for the purpose of stimulating generation of the compound material.

In another embodiment, the compound material is generated as a result of bonding between the p-type impurity, the polysilicon, and oxygen atoms or ions. Also, the cleaning of the substrate can be performed at 60° C. to 80° C. for a predetermined period within a range from approximately 5 minutes to approximately 15 minutes by employing a standard cleaning SC1 process.

In another embodiment, the height of the polysilicon layer in the NMOS region can be less than that of the polysilicon layer in the PMOS region by 100 Å to 500 Å. After the cleaning of the substrate, the method can further include forming a metal layer based on tungsten silicide (WSiₓ) for forming the gate electrode on the polysilicon layer disposed in the NMOS region and in the PMOS region. After the forming of the metal layer, the method can further include forming a nitride-based gate etch mask layer on the metal layer.

In addition to the NMOS region, regions where the height of the polysilicon layer is lower than that of the polysilicon layer in the PMOS region can further include a cell region of the device. A dynamic random access memory (DRAM) is one example of the semiconductor device of the present invention.

According to the present invention, in the dual polysilicon gate formation process, the ion-implantation of the polysilicon layer is carried out and then, the thermal annealing process is employed to selectively form the compound material that decreases the etch rate of the polysilicon layer in the PMOS region. Afterwards, the cleaning process is applied to selectively reduce the thickness of the polysilicon layer in the NMOS region. Through these sequential processes, first, the thickness of the polysilicon layer in the PMOS region is made to be selectively larger, and thus, the penetration of the p-type impurity such as boron into the gate insulation layer can be blocked. Second, this effect on the impairment of the p-type impurity penetration results in a consistently lowered threshold voltage in the PMOS region, further resulting in the realization of a semiconductor device that can be operated in a low voltage mode. Third, it is also possible to reduce a frequency of the defect generation that otherwise would be caused by widely varying threshold voltage. Fourth, since the ion-implantation energy is not lowered, the time of the ion-implantation process does not increase and as a result, the manufacturing productivity can be improved.

### BRIEF DESCRIPTION OF THE DRAWINGS

The above and other features and advantages of the present invention will become more apparent by describing in detail exemplary embodiments thereof with reference to the attached drawings in which:

FIGS. 1 and 2 are cross-sectional views of a typical dual polysilicon gate of a conventional semiconductor device for illustrating a method of forming the same; and

FIGS. 3 through 5 are cross-sectional views of a dual polysilicon gate of a semiconductor device in accordance with a preferred embodiment of the present invention for illustrating a method of forming the same.

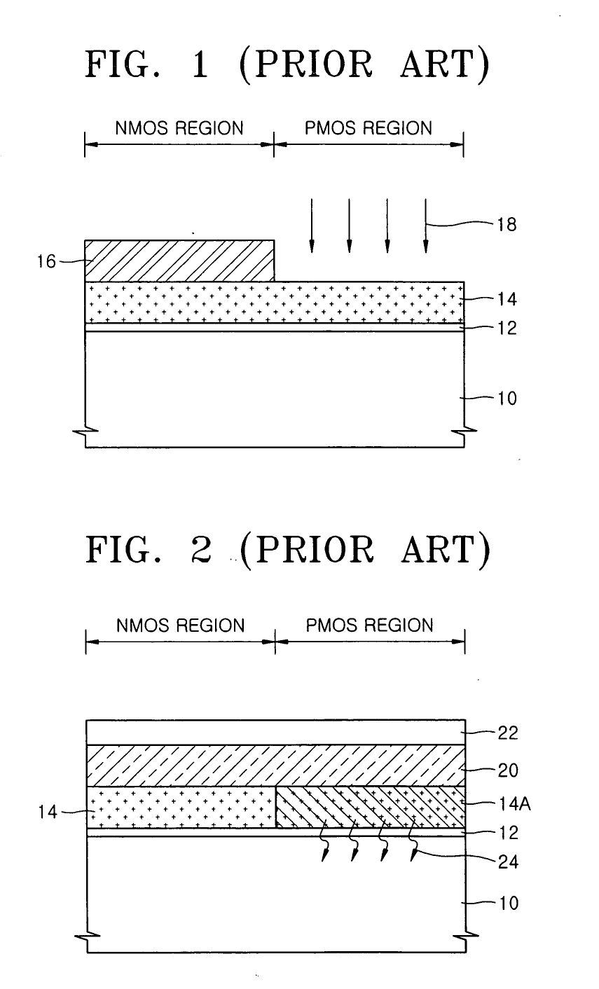

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Like numbers refer to like elements throughout the specification.

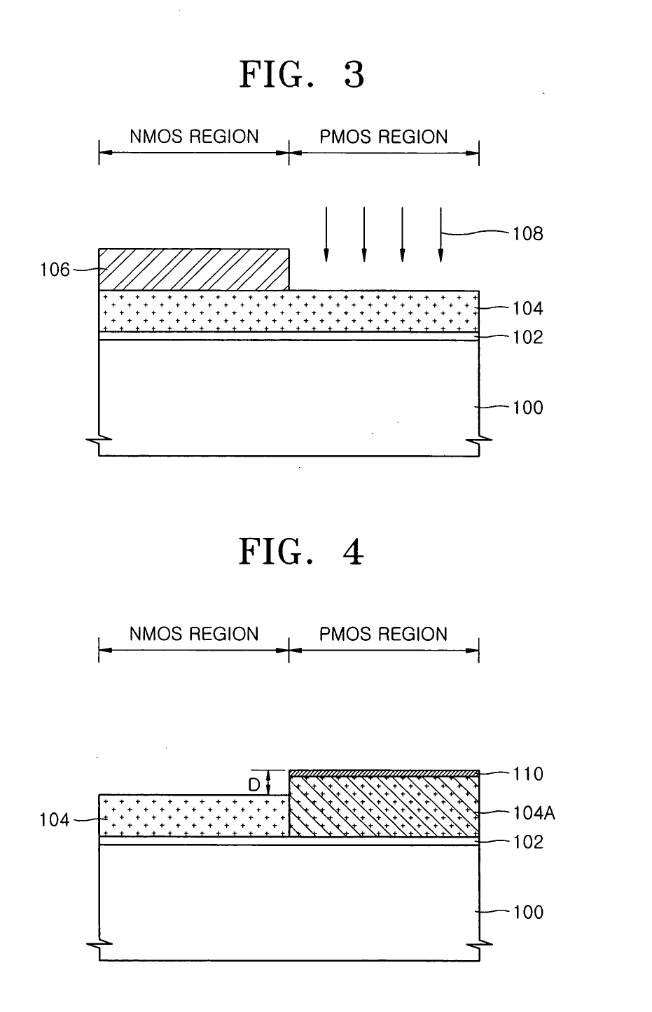

FIGS. 3 through 5 are cross-sectional views of a dual polysilicon gate of a semiconductor device in accordance with a preferred embodiment of the present invention for illustrating a method of forming the same.

Referring to FIG. 3, a typical device isolation process is performed on a semi-finished substrate 100 for forming a dual polysilicon gate of a DRAM. Then, a gate insulation layer 102 is formed on the substrate 100, and a polysilicon layer 104 including an n-type impurity is formed on the gate insulation layer 102 until a thickness of the polysilicon layer 104 is in a range from approximately 500 Å to approximately 900 Å. The n-type impurity includes one of phosphorus (P), arsenic (As) and antimony (Sb). Preferably, the polysilicon layer 104 is capable of shielding a p-type impurity, which will be ion-implanted in a subsequent procedure, from penetrating into the gate insulation layer 102.

A mask pattern 106 masking an n-channel metal-oxide semiconductor (NMOS) region is formed on a predetermined portion of the polysilicon layer 104. A photoresist pattern is an example of the mask pattern 106. After the formation of the mask pattern 106, the aforementioned p-type impurity 108, for instance, boron difluoride (BF₂), is ion-implanted into another portion of the polysilicon layer 104 disposed in a p-channel metal-oxide semiconductor (PMOS) region by using the mask pattern 106 as an ion-implantation mask. At this time, the ion-implantation of the p-type impurity 18 is carried out under a standard energy level ranging from approximately 1 KeV to approximately 20 KeV. Further, rather than the BF₂ ions, boron ions can be used as the p-type impurity 18, and in such a case, the implantation energy level preferably ranges from approximately 1 KeV to approximately 5 KeV.

Referring to FIG. 4, the mask pattern 106 is removed through an ashing process and a strip process. A reference numeral 104A denotes a polysilicon layer that is ion-implanted with the p-type impurity 108. Afterwards, a rapid thermal annealing (RTA) process is performed on a resulting substrate structure obtained after the ashing process and the strip process. The RTA process is specifically carried out at approximately 800° C. to approximately 1,200° C. in an atmosphere of nitrogen gas for approximately 20 seconds to approximately 60 seconds. Herein, to stimulate formation of a compound material 110 in the PMOS region, approximately 1% to approximately 5% of oxygen gas can be added to the nitrogen gas.

Then, a cleaning process is performed at approximately 60° C. to approximately 80° C. for approximately 10 minutes by employing a standard cleaning (SC)-1 process. Thus, approximately 43 Å of the polysilicon layer 104 disposed in the NMOS region is etched away, while an etch rate of the ion-implanted polysilicon layer 104A disposed in the PMOS region is decreased to approximately 0.2 Å. Particularly, the compound material 110 formed in the PMOS region is formed on the ion-implanted polysilicon layer 104A as boron, polysilicon, and oxygen atoms/ions are bonded together. At this time, the compound material 110 has a thickness ranging from approximately 10 Å to approximately 50 Å. Hence, the SC-1 process causes the polysilicon layer 104 in the NMOS region to be etched at a relatively fast rate, thereby lowering the height of the polysilicon layer 104 in the NMOS region by an amount D. On the other hand, the ion-implanted polysilicon layer 104A disposed in the PMOS region is etched at a slow rate, so that the height of the ion-implanted polysilicon layer 104A changes little, or does not change, as a result of the SC-1 process.

Therefore, the height of a gate electrode can be selectively decreased since it is possible to decrease the height of the gate in the NMOS region and to maintain the height of the gate electrode in the PMOS region in which the penetration of the p-type impurity 108 takes place. The discrepancy in height between the polysilicon layer 104 in the NMOS region and the ion-implanted polysilicon layer 104A in the PMOS region, expressed by reference D, is preferably within a range from approximately 100 Å to approximately 500 Å.

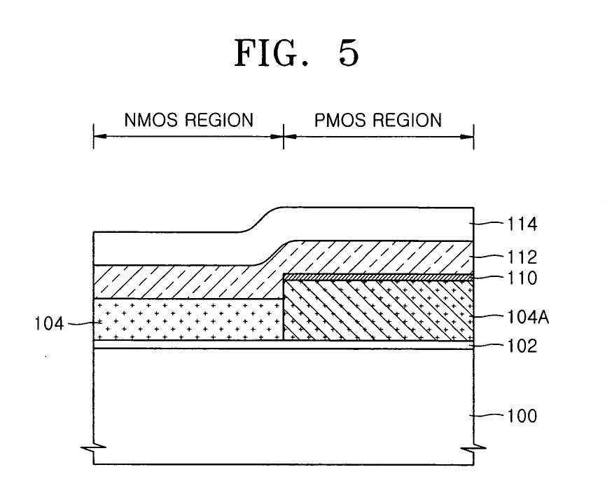

Referring to FIG. 5, after the SC-1 process that causes selective reduction of the height of the polysilicon layer 104 in the NMOS region by the aforementioned range D, a metal layer 112 for use in a gate is formed using tungsten (W) or tungsten silicide (WSiₓ). Subsequently, a gate etch mask layer 114 based on an insulation material such as silicon nitride (SiN) is formed on the metal layer 112. Then, a standard gate process is applied to sequentially etch the gate etch mask layer 114, the metal layer 112, the polysilicon layer 104, and the ion-implanted polysilicon layer 104A, thereby obtaining an intended gate electrode.

Accordingly, in accordance with the disclosed preferred embodiment of the present invention, in the dual polysilicon gate formation process, the ion-implantation of the polysilicon layer is carried out and then, the thermal annealing process is employed to selectively form the compound material that decreases the etch rate of the polysilicon layer in the PMOS region. Afterward, a cleaning process is applied to selectively reduce the thickness of the polysilicon layer in the NMOS region. Through these sequential processes, first, the thickness of the polysilicon layer in the PMOS region is selectively larger. Thus, the penetration of the p-type impurity such as boron into the gate insulation layer in the PMOS region of the device can be blocked. Second, the effect of the impairment of the p-type impurity penetration results in a consistent reduction in the threshold voltage of the PMOS region, further resulting in the realization of a semiconductor device that can be operated in a low voltage mode. Third, it is also possible to reduce the frequency of defect generation caused by a widely varying threshold voltage among transistors. Fourth, since the ion-implantation energy is not lowered, the process time of the ion-implantation process does not increase. As a result, manufacturing productivity can be improved. Fifth, the resistance of the gate can be decreased by increasing the height of the transmission material of the NMOS gate and the cell region while maintaining the same height of the gate.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming a dual polysilicon gate of a semiconductor device, comprising:
forming a polysilicon layer for use in a gate electrode on a substrate divided into a PMOS region and an NMOS region;
forming a mask pattern for masking the NMOS region of the substrate;
ion-implanting a p-type impurity onto a portion of the substrate exposed by the mask pattern in the PMOS region;
removing the mask pattern;
performing a rapid thermal annealing process on the substrate to generate a compound material at a top surface of the polysilicon layer in the PMOS region as a result of bonding between the p-type impurity and the polysilicon layer; and
cleaning the substrate including the compound material in the PMOS region to reduce a height of the polysilicon layer in the NMOS region relative to a height of the polysilicon layer in the PMOS region.

2. The method of claim 1, wherein the polysilicon layer is an n-type impurity doped layer.

3. The method of claim 2, wherein the n-type impurity includes phosphorus.

4. The method of claim 1, wherein the polysilicon layer has a thickness ranging from 500 Å to 900 Å.

5. The method of claim 1, wherein the mask pattern is a photoresist pattern.

6. The method of claim 1, wherein the p-type impurity is one of boron (B) and boron difluoride (BF₂).

7. The method of claim 1, wherein ion-implanting the p-type impurity is performed by using an ion-implantation energy level ranging from 1 KeV to 20 KeV.

8. The method of claim 1, wherein the rapid thermal annealing process is carried out at 800° C. to 1,200° C. in an atmosphere of nitrogen gas for 20 seconds to 60 seconds.

9. The method of claim 8, wherein the rapid thermal annealing process is carried out by adding a trace amount of oxygen gas to the nitrogen gas for the purpose of stimulating generation of the compound material.

10. The method of claim 9, wherein the trace amount of oxygen gas is within a range from 1% to 5%.

11. The method of claim 1, wherein the compound material is generated as a result of bonding between the p-type impurity, the polysilicon, and oxygen atoms or ions.

12. The method of claim 1, wherein cleaning the substrate is performed by employing a standard cleaning SC1 process.

13. The method of claim 1, wherein cleaning the substrate is performed at 60° C. to 80° C.

14. The method of claim 1, wherein the height of the polysilicon layer in the NMOS region is less than that of the polysilicon layer in the PMOS region by about 100 Å to 500 Å.

15. The method of claim 1, further comprising, after the cleaning of the substrate, forming a metal layer for forming a gate electrode on the polysilicon layer disposed in the NMOS region and in the PMOS region.

16. The method of claim 15, wherein the metal layer includes tungsten silicide (WSix).

17. The method of claim 15, further comprising, after the forming of the metal layer, forming a gate etch mask layer on the metal layer.

18. The method of claim 17, wherein the gate etch mask layer is formed using nitride.

19. The method of claim 1, wherein a region where the height of the polysilicon layer is less than that of the polysilicon layer in the PMOS region includes a cell region in addition to the NMOS region.

20. The method of claim 1, wherein the semiconductor device is a dynamic random access memory (DRAM).
